(19) United States
(12) Patent Application Publication
(10) Pub. No.: US 2003/0213992 A1
(43) Pub. Date: Nov. 20, 2003

(54) Semiconductor device

(75) Inventor: Shunji Kubo, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/288,370

(22) Filed: Nov. 6, 2002

(30) Foreign Application Priority Data
May 17, 2002 (JP) 2002-143242(P)

(51) Int. Cl. H01L 29/792; H01L 29/76

(52) U.S. Cl. 257/326; 257/314

(57) ABSTRACT

A semiconductor device is provided, in which drivability of a transistor in a peripheral circuit region is improved. The peripheral circuit region includes a second semiconductor region formed on the semiconductor substrate, a second gate insulating film thinner than a first gate insulating film, a second gate electrode formed on the second gate insulating film, and source and drain regions formed at both sides of the second gate electrodes in the second semiconductor region and doped with an impurity of first conductivity. The source and drain regions include a p-type low-concentration impurity region having an impurity of first conductivity in relatively low concentration and a p-type high-concentration impurity region having an impurity of first conductivity in relatively high concentration.

### BACKGROUND OF THE INVENTION

1. Field of the Invention

The present invention relates to a semiconductor device, and more specifically, to a semiconductor device having a memory cell region.

2. Description of the Background Art

Conventionally, a DRAM (Dynamic Random Access Memory) is known as a semiconductor device that can be highly integrated. The structure of the DRAM is described, for example, in Japanese Patent Laying-Open No. 2001-185705. FIG. 24 is a cross sectional view of a conventional DRAM disclosed in the above publication. Referring to FIG. 24, in the conventional DRAM, a field oxide film 102 is formed on a surface of a semiconductor substrate 101 with a memory cell region 131 and a peripheral circuit region 132. Regions surrounded by field oxide film 102 are active regions, and source and drain regions 107 and 108 are respectively formed therein. Between source and drain regions 107, and similarly between source and drain regions 108, gate electrodes 105 and 106 are respectively formed with gate oxide films 103 and 104 interposed between source and drain regions 107 and 108.

An interlayer insulating film 109 is formed to cover gate electrodes 105 and 106. At interlayer insulating film 109, a contact hole 110 reaching source and drain regions 108 is formed. A capacitor lower electrode 111 is formed to fill contact hole 110. A dielectric film 112 is formed on capacitor lower electrode 111. A capacitor upper electrode 113 is formed on dielectric film 112.

On interlayer insulating film 109, another interlayer insulating film 114 is formed to cover upper electrode 113. Through interlayer insulating films 114 and 109, a contact hole 115 reaching source and drain regions 107 is formed. A bit line 116 is formed on interlayer insulating film 114 to fill contact hole 115.

On interlayer insulating film 114, another interlayer insulating film 117 is formed. Through interlayer insulating film 117, 114 and 109, a contact hole 118 reaching source and drain regions 108 is formed. A plug 119 of tungsten polycide, for example, is filled in contact hole 118. An interconnection layer 120 is formed on interlayer insulating film 117 to be in contact with plug 119. An interlayer insulating film 121 is formed on interlayer insulating film 117 to cover interconnection layer 120.

A field-effect transistor and a capacitor are provided in memory cell region 131, while a field-effect transistor is provided in peripheral circuit region 132. Gate oxide film 103 at the memory cell transistor is thicker than gate oxide film 104 at peripheral circuit region 132. Thus, performance of memory cell region 131 such as leakage cut-off as well as transistor drivability of peripheral circuit region 132 can be improved.

Recently, the transistor drivability at the peripheral circuit region in a DRAM is nevertheless required to be improved. With a conventional DRAM, however, driving a transistor at the peripheral circuit region at higher speed has been difficult.

### SUMMARY OF THE INVENTION

Therefore, the object of the present invention is to solve the above problem by providing a semiconductor device in which a transistor of improved drivability is formed at a peripheral circuit region.

A semiconductor device according to the present invention includes a semiconductor substrate having a main surface, a memory cell region formed on the semiconductor substrate, and a peripheral circuit region formed on the semiconductor substrate. The memory cell region includes a first semiconductor region of a first conductivity formed on the semiconductor substrate, a first gate insulating film formed on the main surface to be positioned on the first semiconductor region, and a first gate electrode formed on the first gate insulating film. The peripheral circuit region includes a second semiconductor region of a second conductivity formed on the semiconductor substrate, a second gate insulating film thinner than the first gate insulating film and formed on the main surface to be positioned on the second semiconductor region, a second gate electrode formed on the second gate insulating film, and source and drain regions formed at both sides of the second gate electrodes in the second semiconductor region and doped with an impurity of the first conductivity. The source and drain regions includes a low-concentration impurity region having an impurity of first conductivity in relatively low concentration and a high-concentration impurity region having an impurity of first conductivity in relatively high concentration.

In the thus structured semiconductor device according to the present invention, the source and drain regions at the peripheral circuit region correspond to a so-called LDD (lightly doped drain) structure. Thus, the drivability of transistor at peripheral circuit region is increased.

Preferably, the peripheral circuit region further includes a third semiconductor region of first conductivity. Each of the first and third semiconductor regions of the first conductivity is formed by injecting the impurity of the first conductivity into the semiconductor substrate at the same processing step. Thus, another transistor may be formed on the third semiconductor region on the peripheral circuit region. Further, since the step of forming the third semiconductor region is performed simultaneously with the step of forming the first semiconductor region, the third semiconductor region can be obtained without increasing the number of manufacturing steps.

More preferably, the semiconductor device further includes a bottom well region of the second conductivity formed to be in contact with the first semiconductor region. Thus, the semiconductor substrate and the first semiconductor region of the first conductivity can be separated by the bottom well region interposed therebetween.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of a semiconductor device according to a first embodiment of the present invention;

FIGS. 2 to 20 are cross sectional views of the semiconductor device illustrated in FIG. 1 in first to nineteenth manufacturing steps;

FIG. 21 is a cross sectional view of a semiconductor device according to a second embodiment of the present invention;

FIG. 22 is a cross sectional view related to a manufacturing method of the semiconductor device illustrated in FIG. 21;

FIG. 23 is a cross sectional view of a semiconductor device according to a third embodiment of the present invention; and

FIG. 24 is a cross sectional view of a conventional semiconductor device.

### DESCRIPTION OF THE PREFERRED EMBODIMENTS

In the following, embodiments of the present invention will be described referring to the drawings. Note that identical or similar parts are identified by the same reference characters and the description thereof will not be repeated.

(First Embodiment)

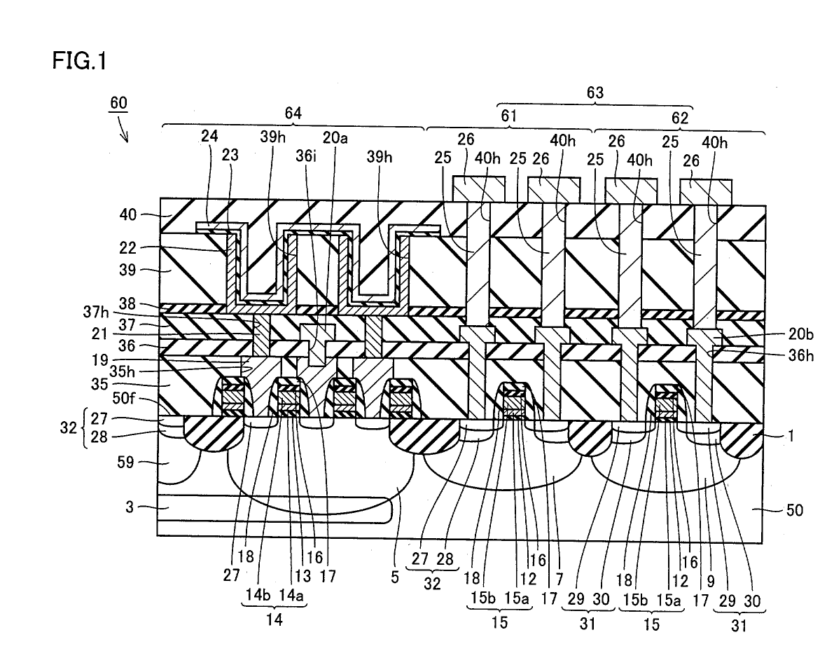

Referring to FIG. 1, semiconductor device (DRAM) 60 according to the present invention includes a semiconductor substrate 50 having a main surface 50f, a memory cell region 64 formed on semiconductor substrate 50, and a peripheral circuit region 63 formed on semiconductor substrate 50. Memory cell region 64 includes a p-type first semiconductor region 5 of a first conductivity formed on semiconductor substrate 50, a first gate insulating film 13 formed on main surface 50f to be positioned on first semiconductor region 5, and a first gate electrode 14 formed on first gate insulating film 13. Peripheral circuit region 63 includes an n-type second semiconductor region 9 of a second conductivity formed on semiconductor substrate 50, a second gate insulating film 12 formed on main surface 50f to be positioned on the second semiconductor region 9 and being thinner than first gate insulating film 13, a second gate electrode 15 formed on second gate insulating film 12, and source and drain regions 31 formed at both sides of second gate electrode 15 in second semiconductor region 9 and doped with an impurity of first conductivity. Source and drain regions 31 include a p-type low-concentration impurity region 29 having an impurity of first conductivity in relatively low concentration, and a p-type high-concentration impurity region 30 having an impurity of first conductivity in relatively high concentration.

Semiconductor device 60 further includes a bottom well region 3 formed to be in contact with first semiconductor region 5.

Semiconductor substrate 50 is formed of a silicon substrate and has main surface 50f. On semiconductor substrate 50, a memory cell region 64 and a peripheral circuit region 63 for controlling memory cell region 64 are formed. Peripheral circuit region 63 includes an NMOS region 61 in which an n-type MOS (Metal Oxide Semiconductor) transistor is formed, and a PMOS region 62 in which a p-type MOS transistor is formed.

Within semiconductor substrate 50, bottom well region 3 doped with an n-type impurity such as phosphorus or the like is formed. First semiconductor region 5 of a p-type well region is formed to be in contact with bottom well region 3.

On main surface 50f of semiconductor substrate 50, a plurality of isolation oxide films 1 are formed, being distanced from each other. Separated by the plurality of isolation oxide films 1, first semiconductor region 5, second semiconductor region 9, third semiconductor region 7, and fourth semiconductor region 59 are respectively formed. First semiconductor region 5 is a p-type well region formed by a deep injection of a p-type impurity, and is in contact with bottom well region 3.

Second semiconductor region 9 is an n-type well region formed by injecting an n-type impurity into semiconductor substrate 50. Third semiconductor region 7 is a p-type well region formed by a shallow injection of a p-type impurity into semiconductor substrate 50, and is in contact with bottom well region 3. Fourth semiconductor region 59 is an n-type well region formed by an injection of an n-type impurity into semiconductor substrate 50.

First and Fourth semiconductor regions 5 and 59 are formed in memory cell region 64. Second semiconductor region 9 is formed in PMOS region 62, while third semiconductor region 7 is formed in NMOS region 61.

On main surface 50f, first gate insulating film 13 formed of silicon oxide film is provided in memory cell region 64. First gate electrode 14 is formed on first gate insulating film 13. First gate electrode 14 is structured with a doped polysilicon layer 14a and tungsten silicide layer 14b. A silicon oxide film 16 and silicon nitride film 17 are deposited on tungsten silicide layer 14b.

Sidewall spacers 18 formed of silicon nitride film are provided on the sides of first gate insulating film 13, first gate electrode 14, silicon oxide film 16 and silicon nitride film 17.

Between adjacent first gate electrodes 14, an n-type low-concentration impurity regions 27 is formed. N-type low-concentration region 27 and first gate electrode 14 constitute a field-effect transistor.

An interlayer insulation layer 35 is formed to cover first gate electrode 14. A contact hole 35h reaching n-type low-concentration impurity region 27 is formed in interlayer insulating film 35. A plug 19 formed of doped polysilicon is provided to fill contact hole 35h. Plug 19 is in contact with n-type low-concentration impurity region 27.

In peripheral circuit region 63, NMOS region 61 and PMOS region 62 are provided with second gate insulating films 12. Second gate electrode 15 are formed on second gate insulating films 12. Second gate electrodes 15 are structured with doped polysilicon layers 15a and tungsten silicide layers 15b. On second gate electrodes 15, silicon oxide films 16 and silicon nitride films 17 are deposited, to which sides sidewall spacers 18 are formed. Second gate insulating film is thinner than first gate insulating film.

A pair of n-type source and drain regions 32 are formed at both sides of gate electrode 15 in third semiconductor region 7 in NMOS region 61. Source and drain regions 32 include n-type low-concentration impurity region 27 with relatively low n-type impurity concentration, and n-type high-concentration impurity region 28 with relatively high n-type impurity concentration. Interlayer insulating films 35 and 36 are deposited on main surface 50f of semiconductor substrate 50.

A pair of p-type source and drain regions 31 are formed at both sides of gate electrode 15 in second semiconductor region 9 in PMOS region 62. Source and drain regions 31 include p-type low-concentration impurity region 29 with relatively low p-type impurity concentration, and p-type high-concentration impurity region 30 with relatively high p-type impurity concentration.

Contact hole 36h reaches source and drain regions 31 and 32. Another interlayer insulating film 36 is formed on interlayer insulating film 35. A contact hole 36i is formed in memory cell region of interlayer insulating film 36. Contact hole 36i reaches plug 19. A bit line 20a is formed on interlayer insulating film 36 to fill contact hole 36i. Another interlayer insulating film 37 is formed to cover bit line 20a.

A contact hole 37h reaching plug 19 is formed on interlayer insulating films 37 and 36. A plug 21 formed of doped polysilicon is provided to fill contact hole 37h.

A silicon nitride film 38 as an etch-stopper is provided on interlayer insulating film 37. An interlayer insulating film 39 is formed on silicon nitride film 38. A contact hole 39h is formed at interlayer insulating film 39 and silicon nitride film 38. Contact hole 39h is provided so as to reach plug 21, interlayer insulating films 38 and 37.

A capacitor lower electrode 22 is provided along the wall of contact hole 39h. Bottom electrode 22 is directly in contact with plug 21 formed of doped polysilicon. A dielectric film 23 formed of tantalum oxide is formed on lower electrode 22. A capacitor upper electrode 24 is formed on dielectric film 23. Top electrode 24 contains titanium nitride.

In peripheral circuit region 63, contact hole 36h is formed at interlayer insulating films 36 and 35. A bit line 20b is provided to fill contact hole 36h. Contact hole 40h is formed at interlayer insulating films 40, 39 and 37 and silicon nitride film 38. A plug 25 formed of metal having high melting point such as tungsten is provided to fill contact hole 40h. An interconnection 26 is formed on interlayer insulating film 40 to be in contact with plug 25. Interconnection 26 is a stacked structure of titanium nitride, aluminum and titanium nitride, with aluminum sandwiched with upper and lower titanium nitrides.

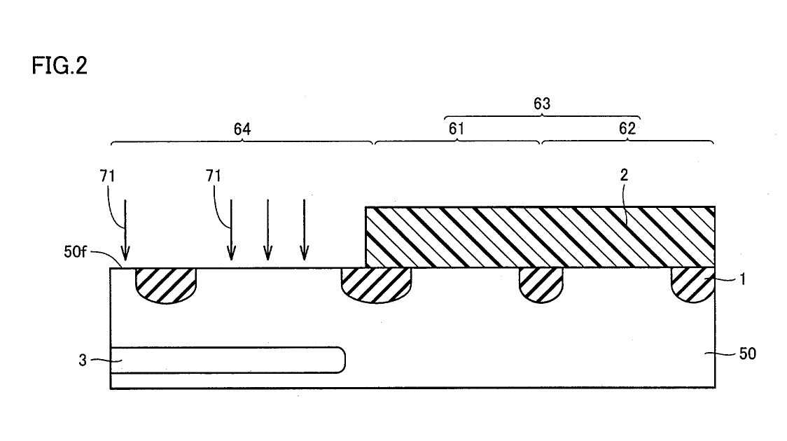

Next, a manufacturing method of semiconductor device 60 shown in FIG. 1 will be described. Referring to FIG. 2, trenches are formed partially on main surface 50f of semiconductor substrate 50, and thereafter filled with insulating film. Thus, isolation oxide films 1 are formed. Then, a resist pattern 2 is formed on main surface 50f, which in turn is used as a mask for injecting an n-type impurity such as phosphorus to the memory cell region 64 at high energy in the direction indicated by an arrow 71. Thus, n-type bottom well 3 is formed as a lower isolating layer.

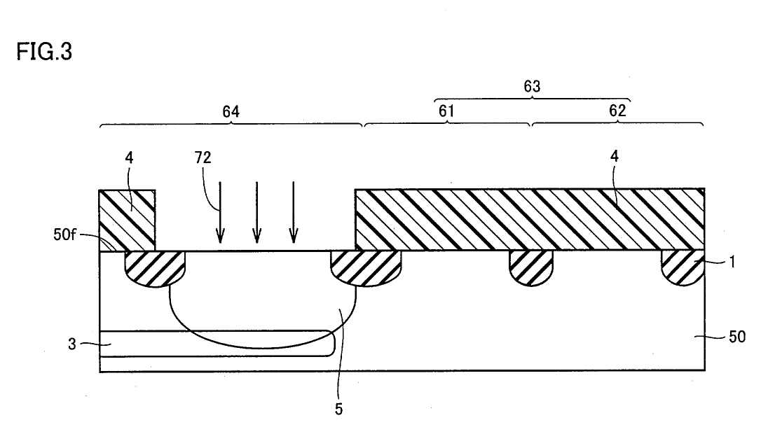

Referring to FIG. 3, a resist pattern 4 is formed on main surface 50f. Resist pattern 4 exposes only the particular region of memory cell region 64, where transistor should be formed. Using this resist pattern 4 as a mask, a p-type impurity such as boron is injected into semiconductor substrate 50 in the direction indicated by an arrow 72. This injection is carried out with relatively high energy in order to improve refresh characteristics. Thus, first semiconductor region 5 of p-type well region is formed.

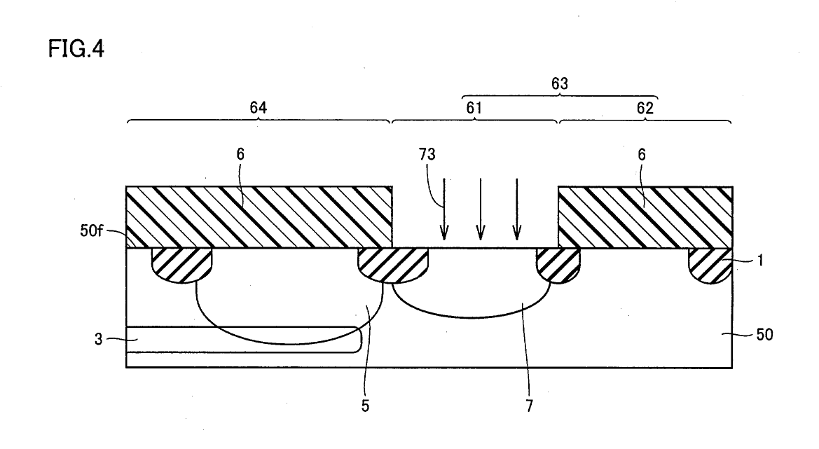

Referring to FIG. 4, a resist pattern 6 exposing NMOS region 61 is formed on main surface 50f. Using resist pattern 6 as a mask, a p-type impurity such as boron is injected into semiconductor substrate 50 in the direction indicated by an arrow 73. This injection is carried out with relatively low energy in order to improve refresh characteristics, specifically, to reduce parasitic capacitance. Thus, third semiconductor region 7 of p-type well region is formed.

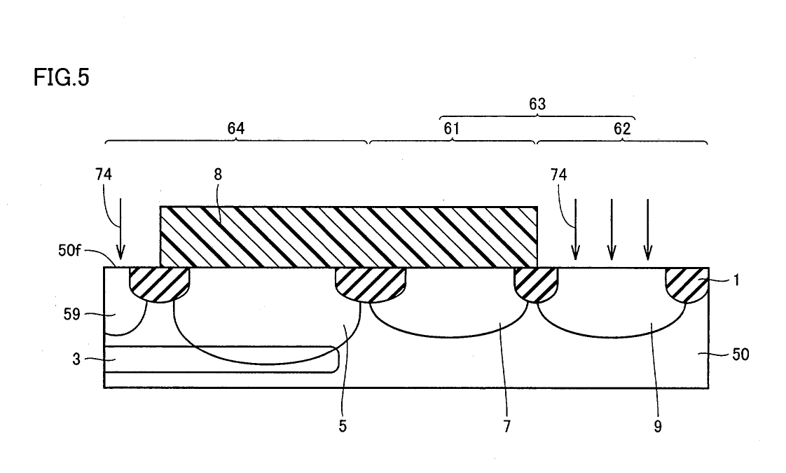

Referring to FIG. 5, a resist pattern 8 is formed so as to expose a part of memory cell region 64 and PMOS region 62. The part of memory cell region 64 exposed by resist pattern 8 is a fixed region for back bias of memory cell. Using this resist pattern 8 as a mask, an n-type impurity such as phosphorus or arsenic is injected into semiconductor substrate 50 in the direction indicated by an arrow 74. Thus, second and fourth semiconductor regions 9 and 59 of n-type well regions are formed.

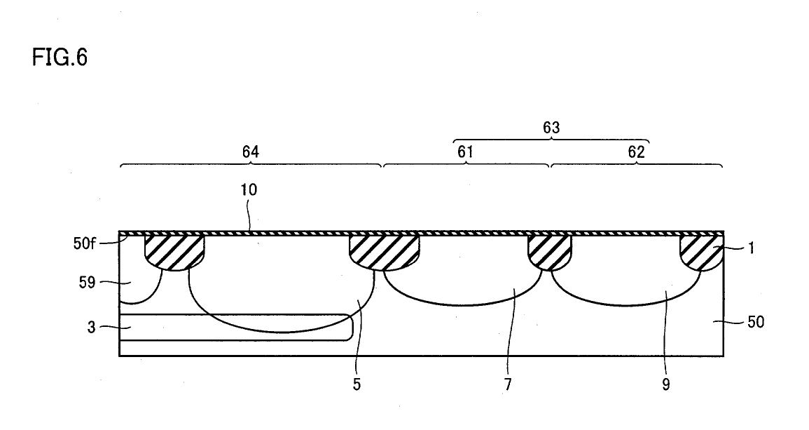

Referring to FIG. 6, a silicon oxide film 10 having a prescribed thickness is formed on entire main surface 50f.

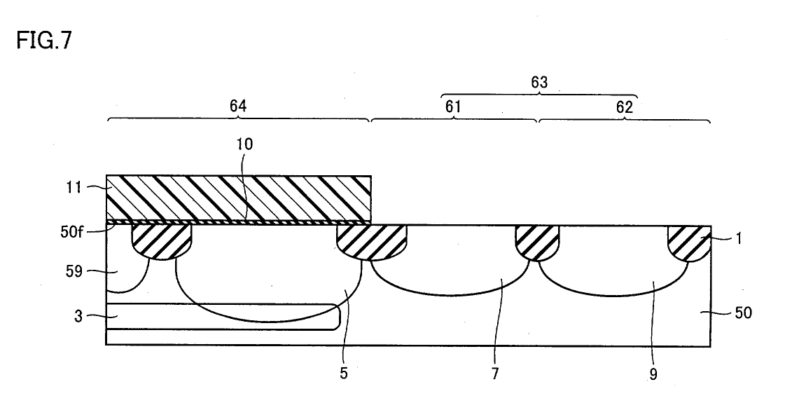

Referring to FIG. 7, a resist pattern 11 is formed so as to cover memory cell region 64. Silicon oxide film 10 is removed by hydrofluoric acid or the like from the region not being covered with resist pattern 11 on memory cell region 64.

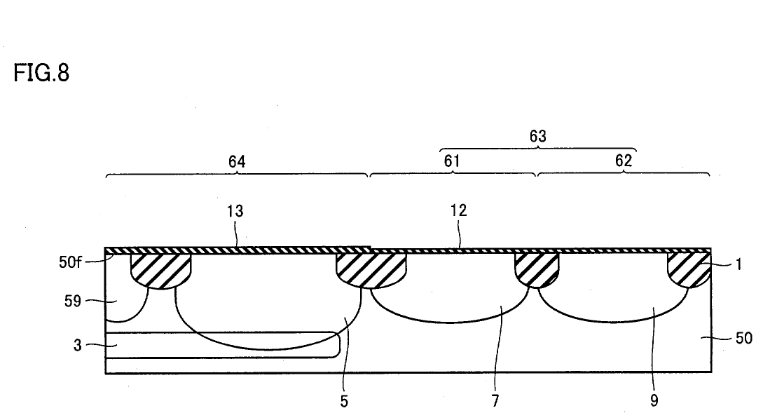

Referring to FIG. 8, by forming new silicon oxide film on main surface 50f entirely, first gate insulating film 13 that is a composite film of two oxide films is formed in memory cell region 64. In contrast thereto, second gate insulating film 12 formed of one silicon oxide film is provided in peripheral circuit region 63. First gate insulating film 13 is thicker than second gate insulating film 12.

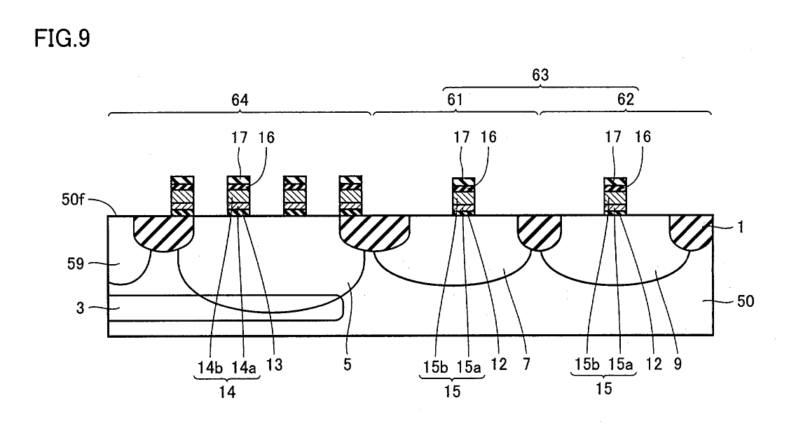

Referring to FIG. 9, a doped polysilicon layer, a tungsten silicide layer, a silicon oxide film (TEOS: tetra-etyle-ortho-silicate), and a silicon oxide film are formed on first and second gate insulating films 13 and 12. By forming a resist pattern thereon and etching them accordingly, doped polysilicon layers 14a and 13a, tungsten silicide layers 14b and 15b, silicon oxide film 16, and silicon nitride film 17 are formed.

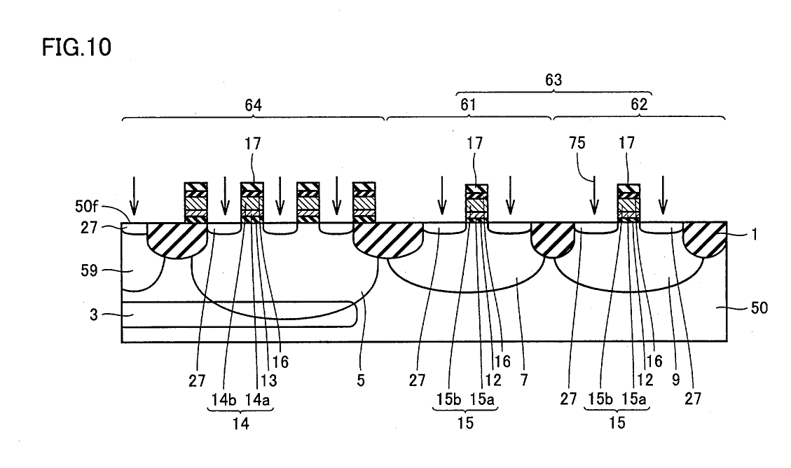

Referring to FIG. 10, an n-type impurity such as phosphorus of relatively low concentration is injected into semiconductor substrate 50 in the direction indicated by an arrow 75 without masks. Thus, n-type low-concentration impurity region 27 formed of n-type impurity region is formed.

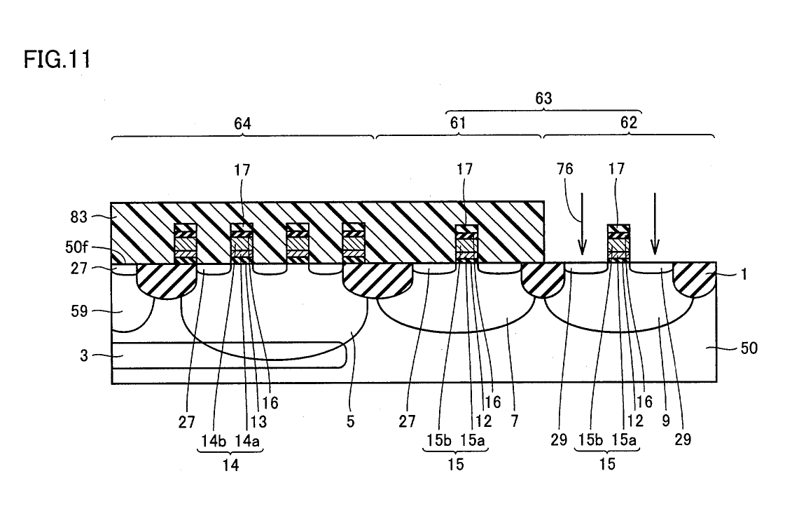

Referring to FIG. 11, a resist pattern 8 is formed so as to expose PMOS region 62. Using resist pattern 83 as a mask, a p-type impurity such as boron is injected into semiconductor substrate 50 in the direction indicated by an arrow 76. Thus, p-type low-concentration impurity region 29 is formed. While n-type low-concentration impurity region 27 is formed in the step represented by FIG. 10, p-type low-concentration impurity region 29 may be formed by injecting boron in higher concentration than that of n-type impurity in n-type low-concentration impurity region 27.

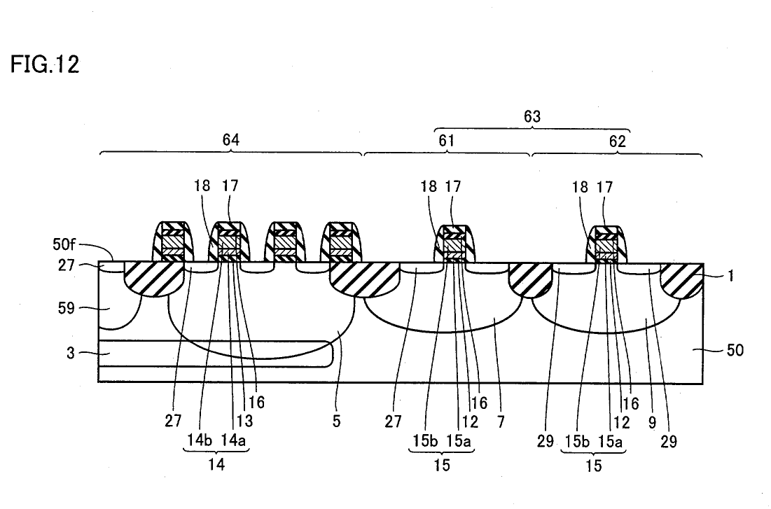

Referring to FIG. 12, a silicon nitride film is formed on main surface 50f to be anisotropically etched. Thus, sidewall spacers 18, which is formed of silicon nitride film, are formed on the sidewalls of first and second gate electrodes 14 and 15.

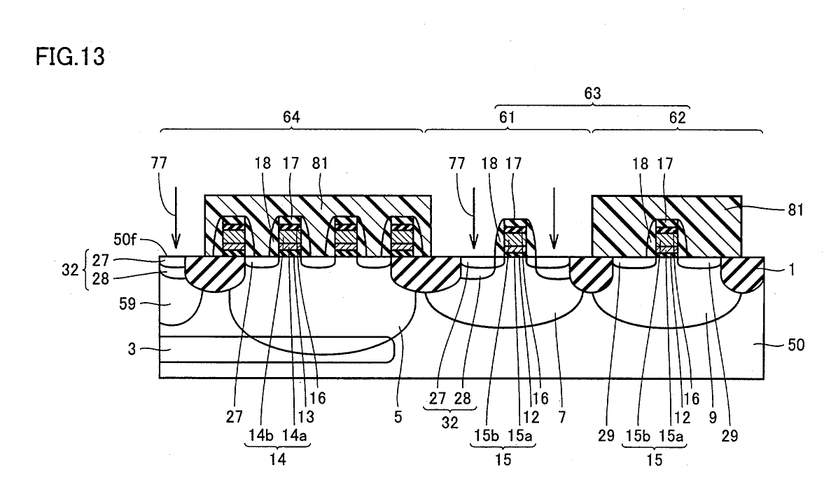

Referring to FIG. 13, a resist pattern 81 is formed to cover the transistor formed at memory cell region 64 and PMOS region 62. Using resist pattern 81 as a mask, by injecting an n-type impurity such as arsenic at relatively high concentration into semiconductor substrate 50 in the direction indicated by an arrow 77, an n-type high-concentration impurity region 28 is formed.

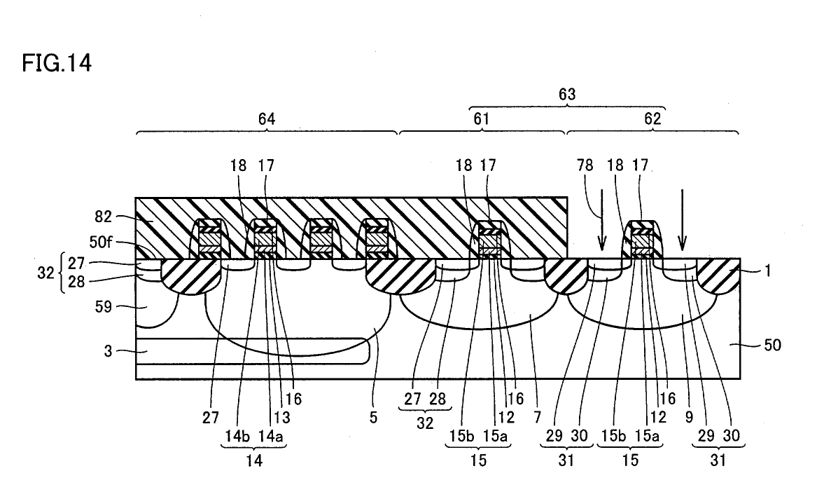

Referring to FIG. 14, a resist pattern 82 which exposes only PMOS region 62 is formed. Using resist pattern 82 as a mask, by injecting an n-type impurity such as boron at relatively high concentration into semiconductor substrate 50 in the direction indicated by an arrow 78, a p-type high-concentration impurity region 30 is formed.

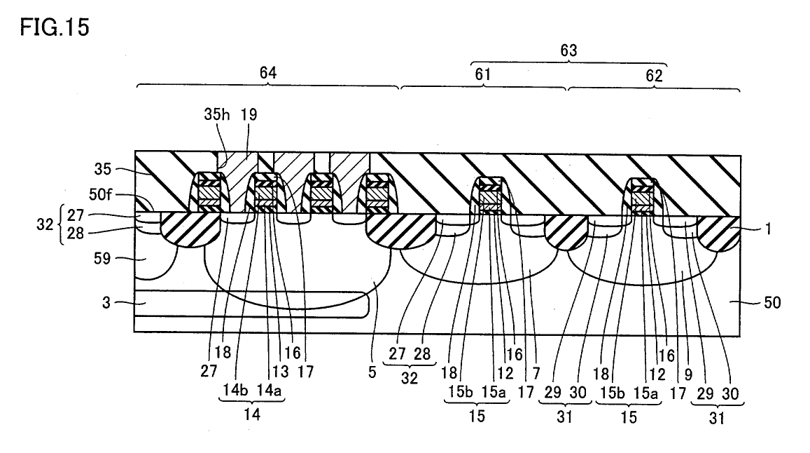

Referring to FIG. 15, after forming a thin silicon nitride film (not shown) on main surface 50f, interlayer insulating film 35 formed of BPTEOS (boro-phospo-tetra-etyle-ortho-silicate) or the like is formed. Contact hole 35h is formed by forming a resist pattern on interlayer insulating film 35 and then etching the same using the resist pattern as a mask. Plug 19 is formed by filling contact hole 35h with doped polysilicon.

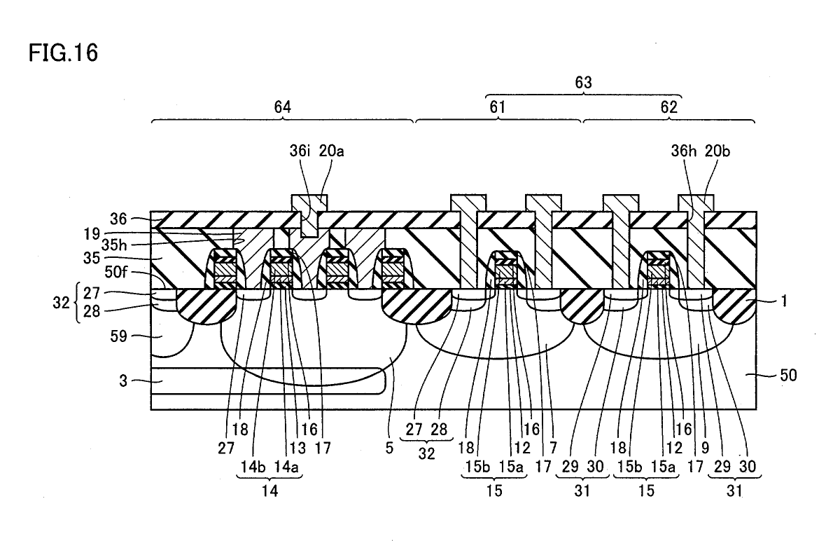

Referring to FIG. 16, interlayer insulating film 36 formed of TEOS or the like is deposited on interlayer insulating film 35. By forming resist pattern on interlayer insulating film 36 and etching interlayer insulating film 36 and 35 according to the resist pattern, contact holes 36h and 36i are formed. Then, contact holes 36h and 36i are filled with a conductive layer formed of titanium nitride and tungsten, which is in turn patterned to form bit lines 20a and 20b.

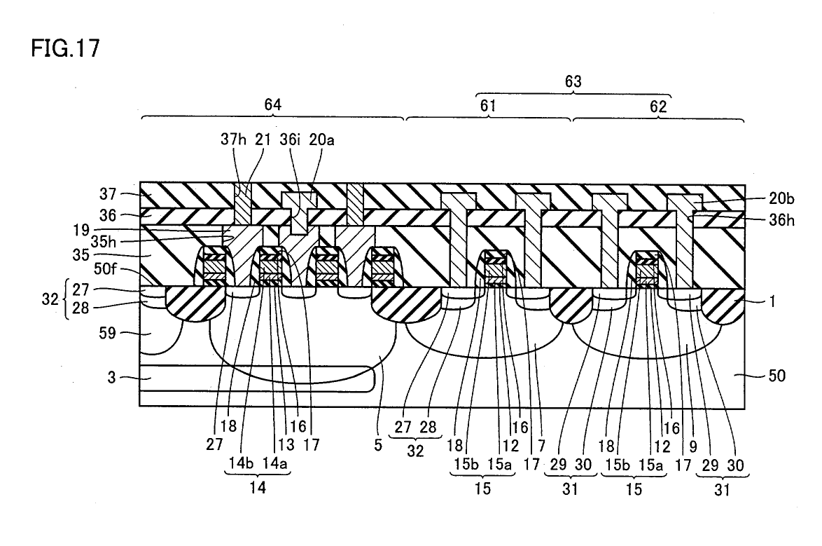

Referring to FIG. 17, interlayer insulating film 37 formed of TEOS or the like is deposited on interlayer insulating film 36. A resist pattern is formed on interlayer insulating film 37, and using the resist pattern as a mask, interlayer insulating film 37 and 36 are etched to form contact hole 37h. Silicon nitride layer (not shown) is formed at the sidewall of contact hole 37h, then further, contact hole 37h is filled with doped polysilicon to form plug 21.

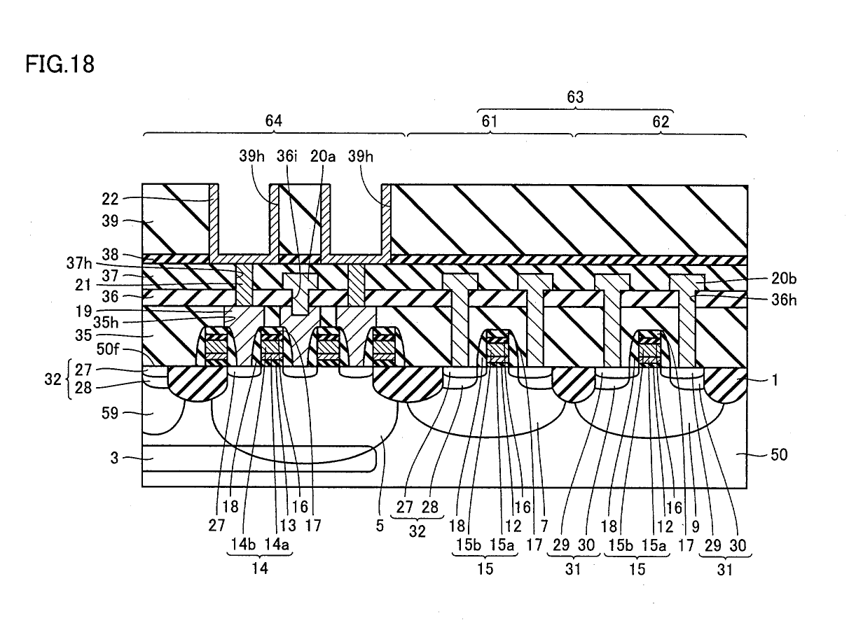

Referring to FIG. 18, silicon nitride film 38 acting as an etch-stopper is formed on interlayer insulating film 37. Further, interlayer insulating film 39 formed of BPTEOS is deposited on silicon nitride film 38. This interlayer insulating film 39 is planarized by CMP (chemical mechanical polishing). A resist pattern is formed on interlayer insulating film 39, and using the resist pattern as a mask, interlayer insulating film 39 and silicon nitride film 38 are etched. Here, the first etching is set to stop at silicon nitride film 38, and by the second etching an opening is formed in silicon nitride film 38. Over the surface including the surface of the cylindrical capacitor, a doped polysilicon film is deposited. Further, surface area may be increased by surface treatment as needed. Note that this process is not illustrated. Then, after covering the inner surface of contact hole 39h with resist, doped polysilicon being exposed is anisotropically etched. Thus, capacitor lower electrode 22 is formed only within contact hole 39h.

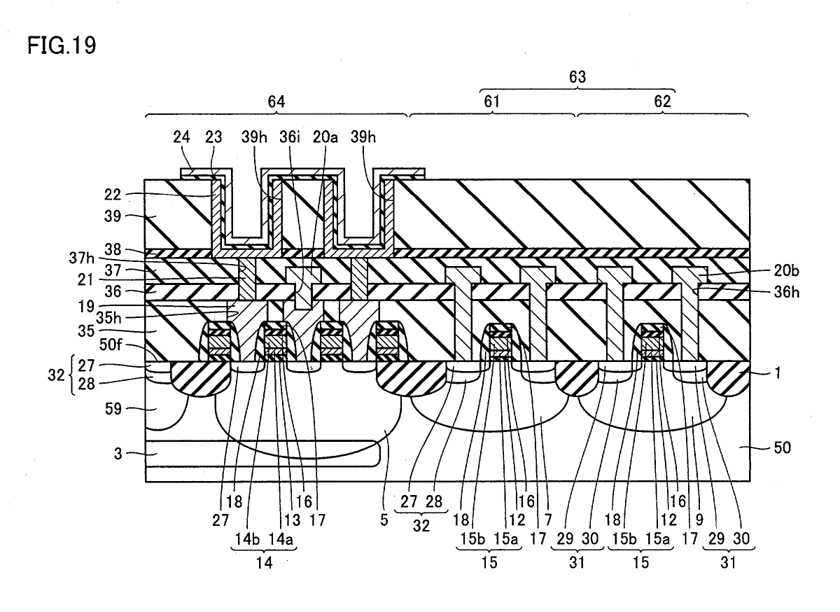

Referring to FIG. 19, a dielectric film formed of tantalum pentroxide and, for example, a titanium nitride film is deposited on lower electrode 22. By forming a resist pattern on these two films and etching them accordingly, dielectric film 23 formed of tantalum oxide and capacitor upper electrode 24 formed of titanium nitride are attained.

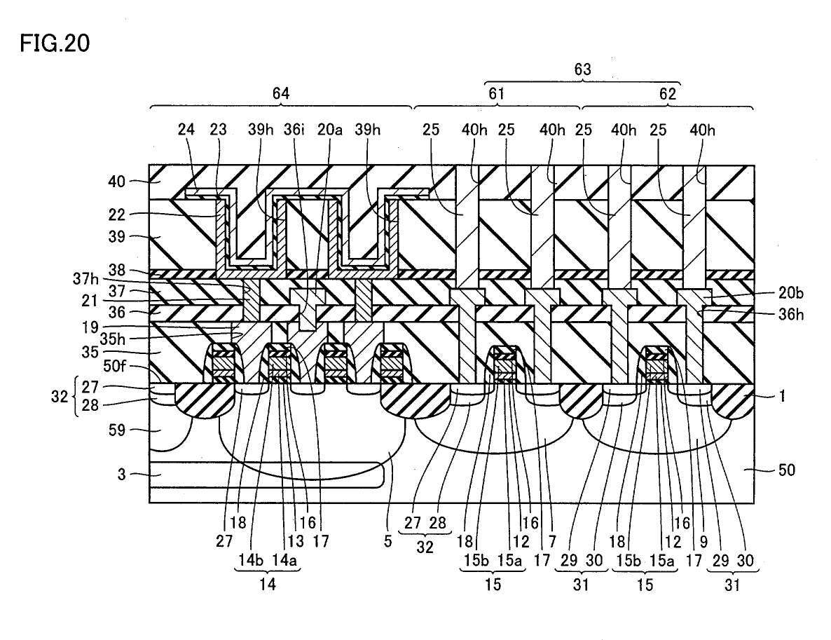

Referring to FIG. 20, interlayer insulating film 40 formed of plasma TEOS or the like is deposited on upper electrode 24. Thereafter, a resist pattern is formed in peripheral circuit region 63, according to which interlayer insulating films 40 and 39 are etched.

Thus, contact hole 40h is formed. Plug 25 formed of titanium nitride and tungsten is provided so as to fill contact hole 40h. Note that titanium nitride acts as a barrier metal.

Thereafter, by arranging interconnection 26 formed of aluminum being sandwiched by titanium nitrides as shown in FIG. 1, semiconductor device 60 of FIG. 1 is completed.

In thus structured semiconductor device according to the first embodiment of the present invention, source and drain regions 31 of the transistor in PMOS region 62 are formed as LDD structure including p-type low-concentration impurity region 29 and p-type high-impurity region 30. Thus, the short channel effect is suppressed and the drivability is increased.

Further, according to the step shown in FIG. 8, second gate insulating film 12 of the transistor of peripheral circuit region 63 is set to be thinner than first gate insulating film 13 of the transistor of memory cell region 64. Thus, both of memory cell region 64 and peripheral circuit region 63 can be controlled by single power source without degrading device characteristics of each region, which results in reduction of chip area. Accordingly, the number of chips per semiconductor substrate 50 increases, which outweighs the increased manufacturing cost for the added single photoresist mask.

(Second Embodiment)

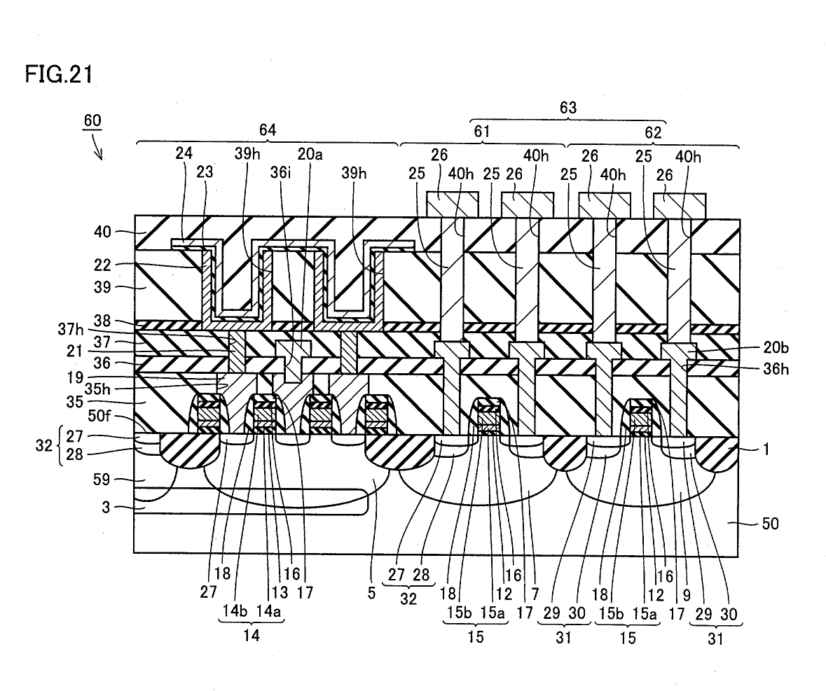

Referring to FIG. 21, a semiconductor device 60 according to a second embodiment of the present invention is different from the semiconductor device according to the first embodiment in that first and third semiconductor regions 5 and 7 are formed approximately at the same depth. First and third semiconductor regions 5 and 7 are both structured by p-type well regions, and having approximately identical impurity concentration distribution.

Peripheral circuit region 64 further includes third semiconductor region 7 of first conductivity. Each of first and third semiconductor regions 5 and 7 is formed by injecting impurity of the first conductivity into semiconductor substrate 50 at the same step.

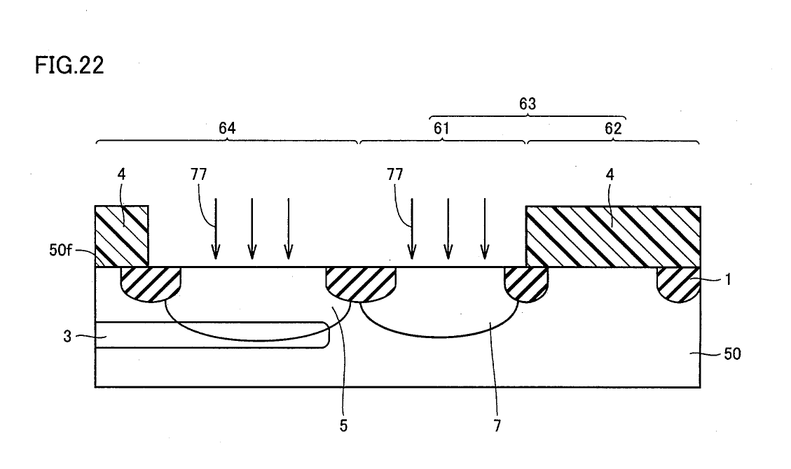

Referring to FIG. 22, when manufacturing the semiconductor device shown in FIG. 21, resist pattern 4 is set to expose a part of memory cell region and NMOS region 61 in the step corresponding to FIG. 3 representing the first embodiment. Thereafter, by injecting p-type impurity such as boron at relatively low energy, in consideration of the performance of peripheral NMOS transistor, in the direction indicated by an arrow 77, first and third semiconductor regions 5 and 7 are formed.

The subsequent steps are similar to those of the first embodiment.

With thus structured semiconductor device according to the second embodiment, firstly the same effect can be attained as the semiconductor device according to the first embodiment. In addition, one photoresist mask can be omitted when product specification for charge storage (refresh) of the DRAM memory cell is less strict, in order to reduce the manufacturing period and costs.

(Third Embodiment)

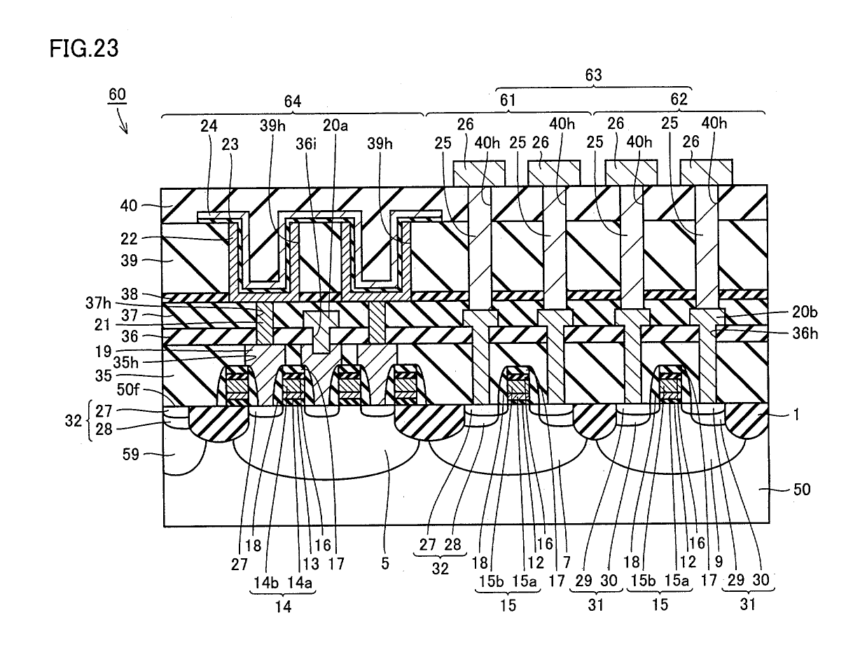

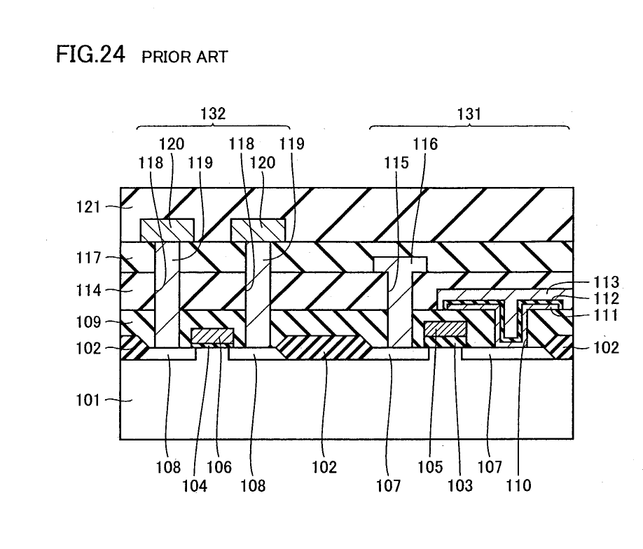

Referring to FIG. 23, a semiconductor device according to a third embodiment of the present invention is different from the semiconductor device according to the first embodiment in that the n-type bottom well region is not present. Such a semiconductor device can be attained by omitting the step of forming bottom well region 3 in the manufacturing process shown in FIG. 2 representing the first embodiment.

With thus structured semiconductor device according to the third embodiment of the present invention, the same effect can be attained as the semiconductor device according to the first embodiment. In addition, one photoresist mask can further be omitted when product specification for charge storage (refresh) of the DRAM memory cell is still less strict, in order to reduce the manufacturing period and costs. Further reduction of chip area can be expected, owing to the eliminated back bias supply region which in turn can be utilized as a memory cell transistor.

According to the present invention, the semiconductor device with improved operational capacity of the peripheral circuit region can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a semiconductor substrate having a main surface;
a memory cell region formed on said semiconductor substrate; and
a peripheral circuit region formed on said semiconductor substrate; wherein
said memory cell region includes a first semiconductor region of a first conductivity formed on said semiconductor substrate,
a first gate insulating film formed on said main surface to be positioned on said first semiconductor region, and
a first gate electrode formed on said first gate insulating film; wherein
said peripheral circuit region includes a second semiconductor region of a second conductivity formed on said semiconductor substrate,
a second gate insulating film thinner than said first gate insulating film formed on said main surface to be positioned on said second semiconductor region,
a second gate electrode formed on said second gate insulating film, and
source and drain regions formed at both sides of said second gate electrodes in said second semiconductor region and doped with an impurity of a first conductivity; and wherein
said source and drain regions include a low-concentration impurity region having an impurity of the first conductivity and a high-concentration impurity region having an impurity of the first conductivity of higher concentration than that of low-concentration impurity region.

2. The semiconductor device according to claim 1, wherein
said peripheral circuit region further includes a third semiconductor region of first conductivity, and each of said first and third semiconductor regions of said first conductivity is formed by injecting said impurity of first conductivity into said semiconductor substrate at the same step.

3. The semiconductor device according to claim 1, further comprising:
a bottom well region of the second conductivity formed so as to contact said first semiconductor region.
